(19) United States
(12) Patent Application Publication
(10) Pub. No.: US 2006/0168975 A1
(43) Pub. Date: Aug. 3, 2006

(54) Thermal and power management apparatus

(75) Inventors: Christopher G. Malone, Loomis, CA (US); Thane M. Larson, Roseville, CA (US); Glenn C. Simon, Auburn, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P., Houston, TX (US)

(21) Appl. No.: 11/046,476

(22) Filed: Jan. 28, 2005

(51) Int. Cl. F24F 7/00; F25D 17/00; H05K 5/00; F25D 23/12

(52) U.S. Cl. 62/180; 62/259.2; 236/49.3

(57) ABSTRACT

A method for processing airflow distribution in a data center comprises monitoring airflow in a ventilation system including a plurality of fans in at least one server in the data center, and controlling cooling in the ventilation system as a function of the sensed airflow.

### BACKGROUND OF THE INVENTION

Computer system reliability depends on environmental stability. An information technology (IT) facility such as a data center typically includes an environmental control system intended to operate each system within a suitable range of conditions.

Data center managers and customers face a growing challenge managing the cooling and electrical specifications of information technology (IT) equipment deployed in data centers. Power and system-level airflow specifications have increased dramatically over the past decade. Nameplate power information on servers is defined as a maximum value defined for regulatory compliance and, accordingly, is much higher than actual power consumption. Typically, manufacturers do not supply system-level airflow specifications and, if specified, only a single maximum airflow requirement is defined in technical documentation that is not readily available to most customers. Ambient air temperature sensors are integrated into most enterprise-class servers, but readings are difficult to access.

### SUMMARY

In accordance with an embodiment of a method for processing airflow distribution in a data center, airflow is monitored in a ventilation system including a plurality of fans in at least one server in the data center, and cooling is controlled in the ventilation system as a function of the sensed airflow.

### BRIEF DESCRIPTION OF THE DRAWINGS

Embodiments of the invention relating to both structure and method of operation may best be understood by referring to the following description and accompanying drawings:

FIG. 1 is a schematic block diagram illustrating an embodiment of an airflow distribution apparatus adapted to map airflow based on fan speed for usage in a data center;

FIG. 2 is a perspective pictorial view depicting an embodiment of a ventilation system for usage in a data center and configured to monitor airflow based on fan speed measurements;

FIGS. 3A, 3B, and 3C are flow charts illustrating embodiments of methods for processing airflow distribution in a data center;

FIG. 4 is a schematic pictorial diagram showing an embodiment of a display of a two-dimensional air flow map;

FIG. 5 is a schematic pictorial diagram showing an embodiment of a display of a three-dimensional air flow map; and

FIG. 6 is a schematic pictorial diagram illustrating a perspective view of a data center that implements the illustrative thermal and power management techniques.

### DETAILED DESCRIPTION

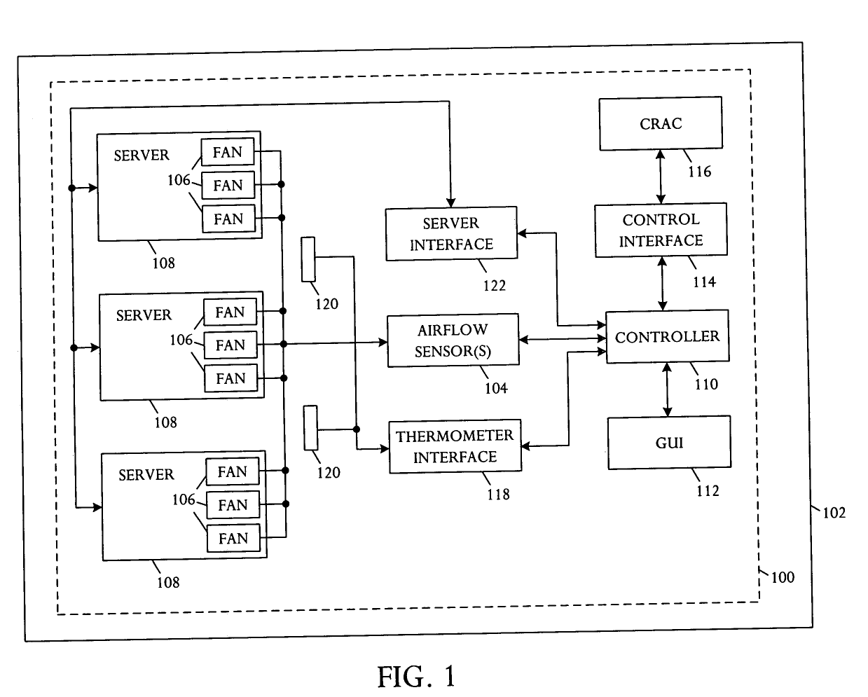

Referring to FIG. 1, a schematic block diagram illustrates an embodiment of an airflow distribution apparatus 100 for usage in a data center 102. The airflow distribution apparatus 100 comprises one or more airflow sensors 104 coupled to a plurality of fans 106 in one or more servers 108 in the data center 102. A controller 110 is coupled to the airflow sensors 104 and is configured or encoded with a computable readable program code for processing airflow distribution in the data center 102. The controller 110 can monitor airflow for the multiple fans and control cooling in the data center 106 as a function of the sensed airflow.

In one illustrative embodiment, the airflow sensors 104 can be tachometers, pressure sensors, anemometers, and other types of sensors that can be used to determine airflow measurements. For example, a tachometer may be used to monitor fan speed, typically in revolutions per minute (RPM). Fan speed readings from the tachometer may be converted to air flow readings using conventional fluid dynamic modeling and calculation. Similarly, fluid dynamic relationships and models are used to convert pressure readings into airflow measurements. Other configurations may use anemometers to direct measure airflow. In some embodiments, the same sensor type may be used for all airflow sensors 104. In other embodiments, various combinations of sensor type may be implemented.

The controller 110 can implement one or more of several monitoring, analysis, and control techniques. For example, the controller 110 may be configured to generate a real-time dynamic airflow mapping from the sensed airflow. In some embodiments, the controller 110 maps airflow in two dimensions, creating a data airflow map in a horizontal plane. In other embodiments, the controller 110 maps airflow in three dimensions as a function of the sensed airflow and fan location not only in the horizontal plane but also taking into consideration height of the airflow pattern within the data center room. The dynamic airflow reading may be accessed by a system manager or user to view conditions in the current operating environment including current operating loads, such as power consumption and software execution load.

An airflow distribution apparatus 100 may further include a graphical user interface 112. The controller can use the graphical user interface 112 to display a real-time dynamic airflow mapping that describes the current data center configuration and airflow throughout locations in the data center configuration. Generation of the mapping and display of the mapping on the graphical user interface 112 enables the airflow distribution apparatus 100 to be used for manual airflow configuration control. A data center administrator may use the mapping information to determine suitable settings for air conditioning equipment and ventilation gratings throughout the data center 102.

In addition to supplying information for manual configuration of the data center 102, in some embodiments or in some conditions, the airflow distribution apparatus 100 may enable automatic control of ventilation. A control interface 114 may be coupled to a computer room air conditioning (CRAC) system 116 and the controller 110 coupled to the CRAC system 116 and further configured to control the CRAC system 116 as a function of the airflow mapping. The controller 110 may include a feedback loop to control air supply by the CRAC system 116 to track consumption of heat dissipating devices at any time. In one embodiment, the feedback loop acquires fan speed information from one or more tachometers, compares the fan speed information to coefficients correlating fan speed to airflow, and manipulates airflow control actuators according to the comparison. Various configurations may adjust source airflow from the CRAC system 116, perforated tile settings, and the like.

A server 108, computer, or other electronic device generally includes one or more internal fans 106 to enable local interior cooling. Fan speed is set, also local to the server 108, as a function of inlet ambient temperature or temperature of an interior heat-sensitive component, typically the central processing unit (CPU). A temperature management control logic local to the server typically runs the internal fan or fans at a minimum possible fan speed for current conditions to control acoustics for a predetermined ambient temperature. If the CPU temperature exceeds a threshold value, then the temperature management control logic increases fan speed to a higher level. Commonly the individual servers, computers, or devices implement local internal temperature management control. In some configurations, the rack holding the servers, computers, or devices may alternatively or additionally supply temperature management capabilities. The illustrative airflow distribution apparatus 100 monitors airflow, for example based on measurements of fan speed from a tachometer implemented with the fans, which results from operation of the local temperature management capabilities as an indication of airflow. Other embodiments may use other sensor types such as anemometers, pressure sensors, thermometers, or other airflow sensors. The airflow sensors may be uniform in type, or may include a combination of sensor types.

In other monitoring and/or automatic control configurations, the airflow distribution apparatus 100 may include a thermometer interface 118 adapted to couple to at least one thermometer 120 located in one or more locations in the data center 102. The controller 110 is coupled to the thermometer interface 118 and operates to measure ambient temperature in various locations in the data center 102 and map airflow in multiple dimensions as a function of sensed airflow readings and fan location. The controller 110 may also map data center ventilation in multiple dimensions as a function of the ambient temperature measurements at the various locations and the airflow mapping.

Some ventilation monitoring and/or automatic control configurations of the airflow distribution apparatus 100 may include a server interface 122 adapted to connect to a multiple servers 108 in the data center 102. The controller 100 is coupled to the server interface 122 and operates to monitor power consumption in the various servers 108 and to map airflow in multiple dimensions as a function of sensed airflow and fan location. The controller 110 may also map data center ventilation as a function of server power consumption and the airflow mapping. In some embodiments and/or conditions, the controller 110 may monitor software execution load in the multiple servers 108 and map airflow in multiple dimensions as a function of sensed airflow and fan location. The controller 110 may also map data center ventilation based on server software execution load and the airflow mapping.

Some ventilation monitoring and/or automatic control configurations of the airflow distribution apparatus 100 may include both the thermometer interface 118 and the server interface 122. The controller 110 can monitor any combination of the parameters and conditions including ambient temperature, power consumption, software execution load, and system airflow. The controller 110 maps airflow in multiple dimensions as a function of sensed airflow readings and fan location, and maps data center ventilation based on the monitored parameters and conditions, in combination with the airflow mapping.

The airflow distribution apparatus 100 enables simple access to measurements such as local external ambient temperature, system airflow, and power consumption for the plurality of servers 108 in the data center 102. The controller 110 functions as central tool that processes and analyzes the measurements, enabling data center manages and/or automatic tools to ensure that information technology equipment has adequate cooling and power. The controller 110 may also identify hot spots and enable experimentation with reductions in computer room air conditioning (CRAC) power consumption and the like.

The illustrative airflow distribution apparatus 100 is a tool enabling simplified field measurement of system airflow information in comparison to other measurement techniques. In the other techniques, technicians measure values for each system with thermocouples and current probes, time-consuming and labor-intensive techniques that represent only a single moment in time in a continuously changing environment. The illustrative technique enables measurement and availability of the illustrative parameters and conditions to system managers, users, and customers. The airflow distribution apparatus 100 further enables the information to be obtained without additional specialized electronics.

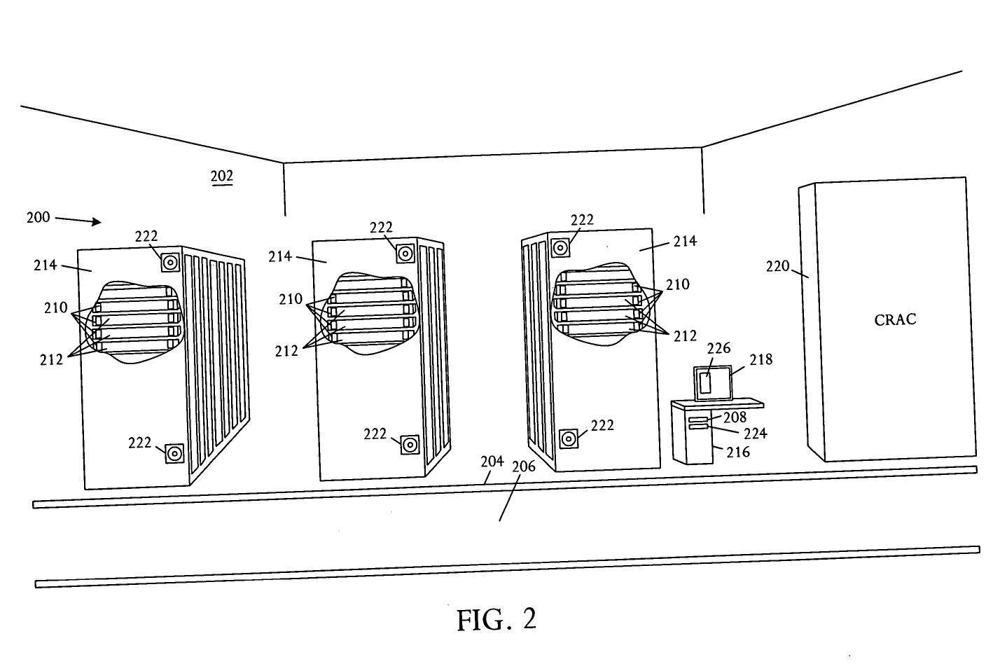

Referring to FIG. 2, a perspective pictorial view depicts an embodiment of a ventilation system 200 for usage in a data center 202. The ventilation system 200 comprises a raised-floor 204 overlying an under-floor plenum space 206. Typically, the plenum space 206 is pressurized, although the illustrative structures and techniques may be functional using a non-pressurized plenum space. One or more airflow sensors 208 are coupled to a plurality of fans 210 in multiple servers 212 arranged in one or more cabinets 214 in the data center 202. A controller 216 is coupled to the airflow sensors 208 and operates to monitor airflow readings for the fans 210 and map airflow in multiple dimensions as a function of sensed airflow readings and locations of the fans 210 in the data center 202.

In various implementations, different types of airflow sensors 208 may be included in the ventilation system 200. For example, fans 210 commonly incorporate a tachometer, enabling airflow to be determined from fan speed. Other types of airflow sensors 208 may be implemented, such as anemometers, pressure sensors, and others. The system 200 may uniformly incorporate airflow sensors of the same type or may include a combination of sensor types. Similarly, a system 200 may include various models and sizes of a particular airflow sensor type, with the controller 216 using information relating to the various sensors to account for differences in performance during computation and mapping of airflow readings.

The ventilation system 200 may includes a graphical user interface 218 that can be used by a system administrator to review the sensed airflow readings and use the readings to configure the system 200. The controller 216 is configured to display measured and monitored information via the graphical user interface 218 to create a real-time dynamic airflow mapping which describes the current data center configuration and airflow throughout locations in the data center configuration.

The ventilation system 200 has a computer room air conditioning (CRAC) system 220 which is adapted to ventilate the data center 202. The controller 216 may control the computer room air conditioning (CRAC) system 220 based on the airflow mapping.

In some embodiments, the ventilation system 200 may perform monitoring of other parameters and conditions to supplement airflow information. For example, in some configurations one or more thermometers 222 may be distributed to one or more locations in the data center 202. The controller 216 may measure ambient temperature in various locations in the data center 202 and map airflow in multiple dimensions as a function of sensed airflow readings and fan location. The controller 216 can map data center ventilation as a function of the airflow mappings and the ambient temperature measurements in the one or more locations.

Similarly, the ventilation system 200 may have a server interface 224 communicatively coupled to multiple servers 212 in the data center 202. The controller 216 may be programmed to access and monitor various parameters and conditions such as server power consumption, software execution load, and the like. The controller 216 typically maps airflow information derived from airflow of the multiple fans 210 distributed in the servers 212 throughout the data center 202. The controller 216 may further map system ventilation based on the airflow mapping, optionally in combination with other monitored parameters such as one or more of power consumption and software execution load.

Some ventilation system embodiments may use any suitable combination of measurements and readings, for example including local ambient temperature, server power consumption, server software execution load, and the like, in combination with airflow mappings derived from airflow measurements, to determine mappings of system ventilation. The resulting system ventilation maps may be used, either manually by system administrative personnel or automatically by the controller or other control devices, to configure the ventilation system 200 as desired.

In the illustrative embodiment, monitoring and control functionality can be implemented in controllers 216 such as server or computer system central processing units (CPUs) in individual equipment items that have one or more fans. Each controller 216 may have a capability to report airflow rate at a selected time or at selected time intervals.

In some embodiments, the ventilation system 200 may include a management application 226 which manages the various parameters and conditions. For example, Openview™ and System Insight Manager™ for Integrity™ servers both made available by Hewlett-Packard Company of Palo Alto, Calif. may be implemented to handle the information. Openview™ automates change and configuration management of software across any computing device or platform to accelerate service delivery, reduce operation costs, and improve service. Openview™ enables information technology managers to address business priorities through increased visibility and control of client software. System Insight Manager™ performs hardware fault, asset, and configuration management for Hewlett-Packard systems and servers including delivery of rapid deployment and performance management, and workload and partition management. System Insight Manager™ can be extended with management for clients, storage, printers and power products, and can manage various platforms through industry standard management protocols.

High-level applications such as Openview™, System Insight Manager™, or similar packages may be used to coordinate thermal monitoring and/or control operations for a very large number, for example tens, hundreds, or more, servers, devices, and components. The high-level application can aggregate information while enabling monitoring of particular elements, for example addressed as a particular server in a specific rack. The high-level application may also perform various operations such as load balancing, analysis of ventilation in the vicinity of a rack, and control of CRAC and venting of perforated tiles.

Various types of sensors may be used in multiple servers and computer systems to track temperature and other parameters in the data center 202. The different types of data are input into the management tool 226 to facilitate ventilation management.

Airflow mapping and, in some configurations, other monitored data supply high level information relating to the amount of air flowing through the ventilation system 200. The high level information is useful in managing cooling air supply to the data center 202. Heat dissipating elements, such as servers 212 and other devices and components, in racks or cabinets in the data center 202 draw some amount of air. If the amount of cooling air supplied by the computer room air conditioning (CRAC) system 220 is insufficient in the area surrounding a particular dissipating element, then the element will draw heated air from surroundings to supply the consumed airflow. Recirculation of heated air may cause overheating of the dissipating element. An illustrative ventilation system 200 dynamically monitors airflow based on fan speed, thereby supplying information relating to current operations of the dissipating elements within the data center 202, information that is traditionally not available. In other embodiments, airflow may be sensed using anemometers, pressure sensors, or others. In traditional operation, a data center designer supplies a customer with one item of data—maximum airflow. Unfortunately, maximum airflow is the maximum amount of air that would ever be drawn by the system at maximum ambient air temperature with components loaded into the system to full capacity. Accordingly, the maximum airflow specification is usually irrelevant to operating conditions and constraints. Most systems implement a fan control functionality that adjusts fan speed based on ambient air temperature and accordingly draw much less airflow.

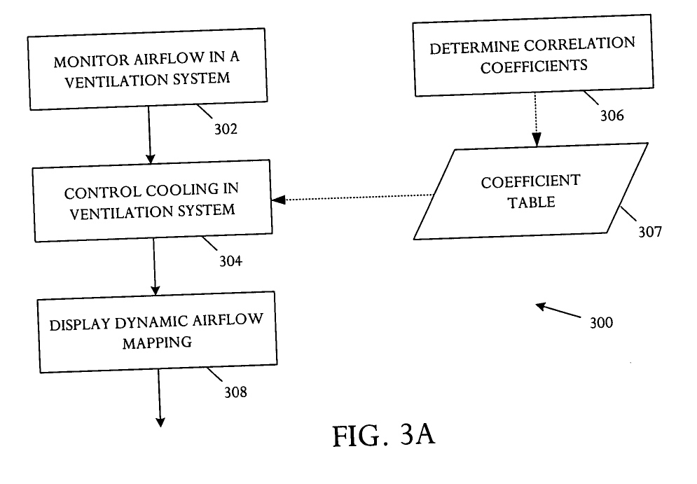

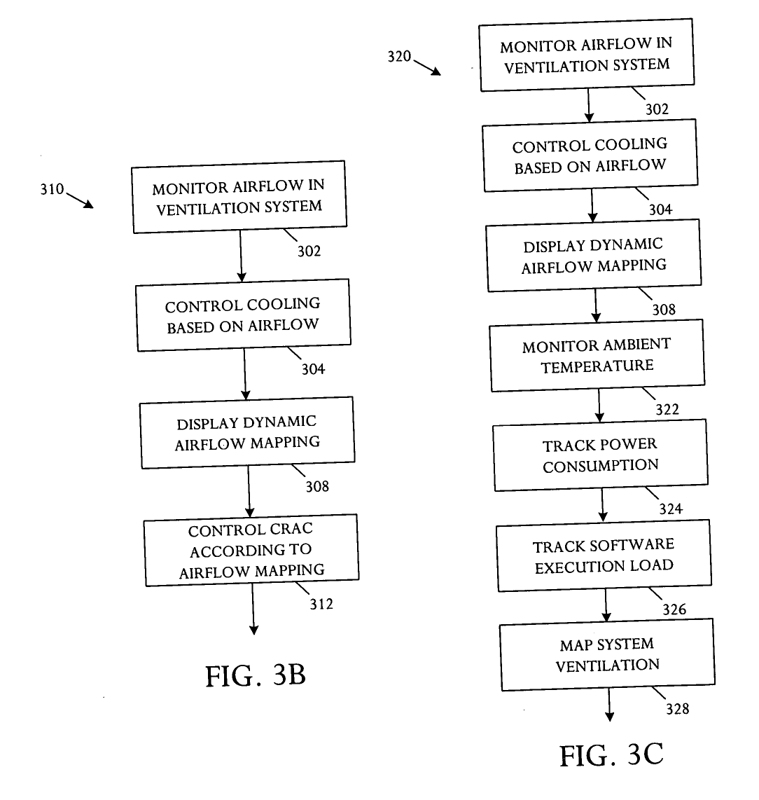

Referring to FIG. 3A, a flow chart illustrates an embodiment of a method 300 for processing airflow distribution in a data center. The method 300 comprises monitoring 302 airflow in a ventilation system including a plurality of fans in at least one server in the data center. Cooling in the ventilation system is controlled 304 as a function of the sensed airflow.

In some embodiments, airflow may be determined from fan speed using correlation coefficients relating fan speed of fans within the data center to airflow. In other embodiments, other types of sensors may be used, such as pressure sensors, anemometers, and the like. The correlation coefficients may be determined 306 during a system thermal characterization operation and saved in a table 307 for usage by the airflow mapping action 304. The thermal characterization operation typically involves acquisition of actual airflow measurements at multiple locations in a data center, for example within or external to various racks and cabinets holding multiple servers, computational and storage devices, and other heat dissipating components. Ambient temperature measurements, power consumption, software execution load measurements, and others may similarly be monitored and saved during thermal characterization.

Fan speed measurements for multiple fans in various servers and elsewhere in the data center may be measured and saved. Similarly, pressure values in various locations in the ventilation system may be monitored and stored with reference to measured airflow values. Wind direction and speed may be directly monitored using anemometers. Accordingly, correlation coefficients can be determined based on actual data correlation of fan speed and/or pressure and airflow measurements. The correlation coefficients may be determined from measurements total airflow through a system in combination with tachometer readings from all fans operating in combination and/or all pressure sensors to create a real-time dynamic airflow measurement.

The system thermal characterization operation may take into consideration variations in equipment, including fans. For homogeneous equipment, a 1:1 correspondence can be made between fan speed and/or pressure measurements and airflow measurements, or in some configurations between airflow and the combination of fan speed and/or pressure and ambient temperature. For a non-homogeneous system with different kinds of equipment, differences in correspondence between fan speed and airflow for the different types of servers are taken into consideration. Similarly, the correlation coefficients can be derived taking differences in airflow and ambient temperature in different parts of the data center into consideration. For highly variable non-homogeneous implementations, thermometer readings are useful in combination with thermocouple measurements to determine the correlation coefficients.

Once the correlation coefficients are derived and stored, the system can monitor fan tachometers and report system airflow based on system fan speeds to supply information which is unavailable in conventional systems. Accordingly, airflow information derived according to tachometer readings is made available in an essentially cost-free operation since fan tachometers are routinely included in standard fan designs. The illustrative technique exploits the tachometer readings simply by the act of creating a table that correlates fan speed to system airflow, for example during system thermal characterization. The airflow characterization may be used by a customer to control flow of cooling air to dissipating elements in the data center based on actual operating conditions.

The thermal characterization operation may implement a test suite application which derives the fan speed-airflow correlation coefficients and generates a correlation coefficient table for usage during subsequent monitoring and/or control operations.

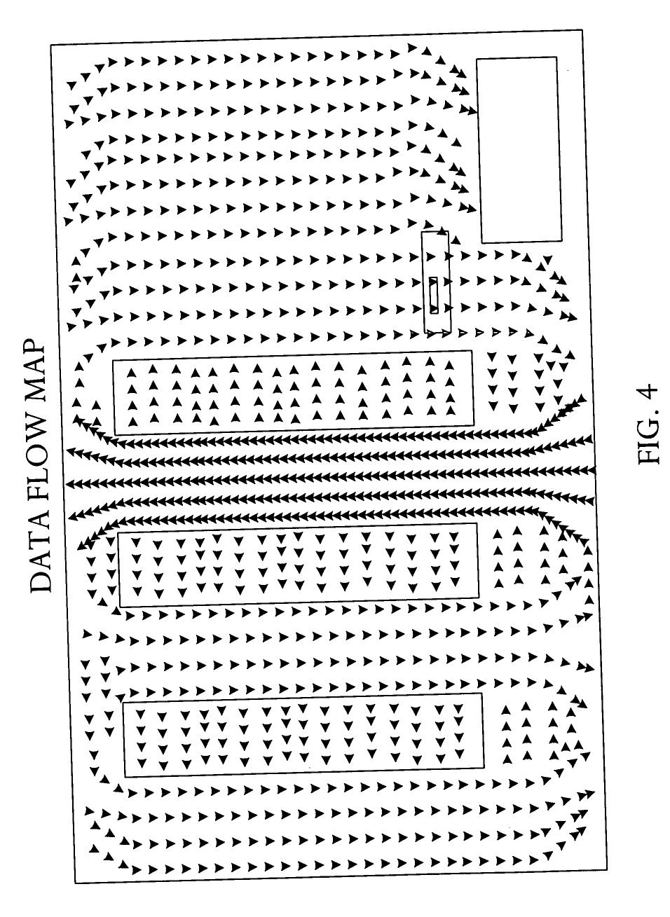

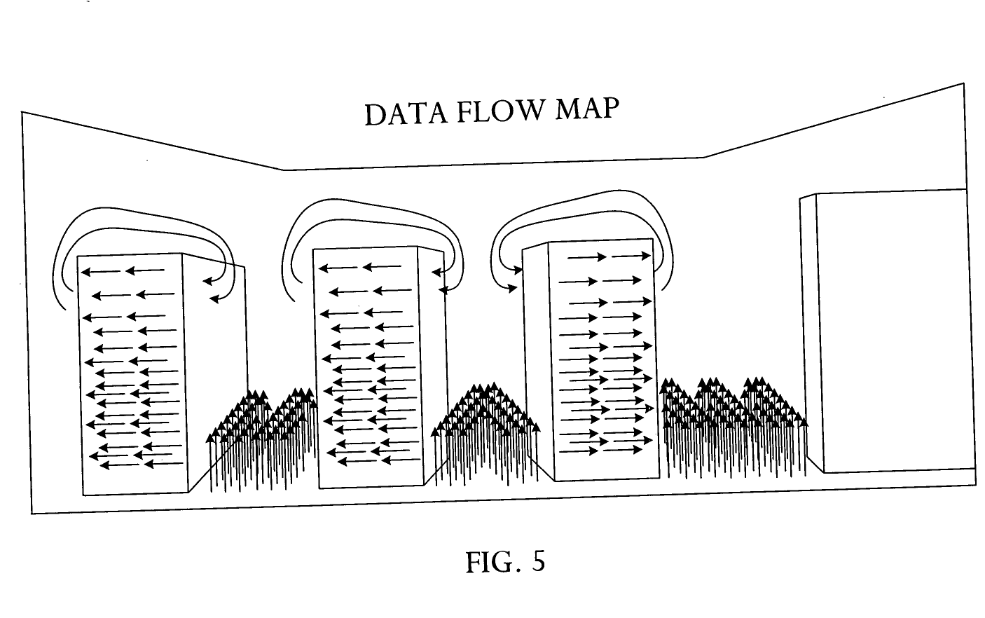

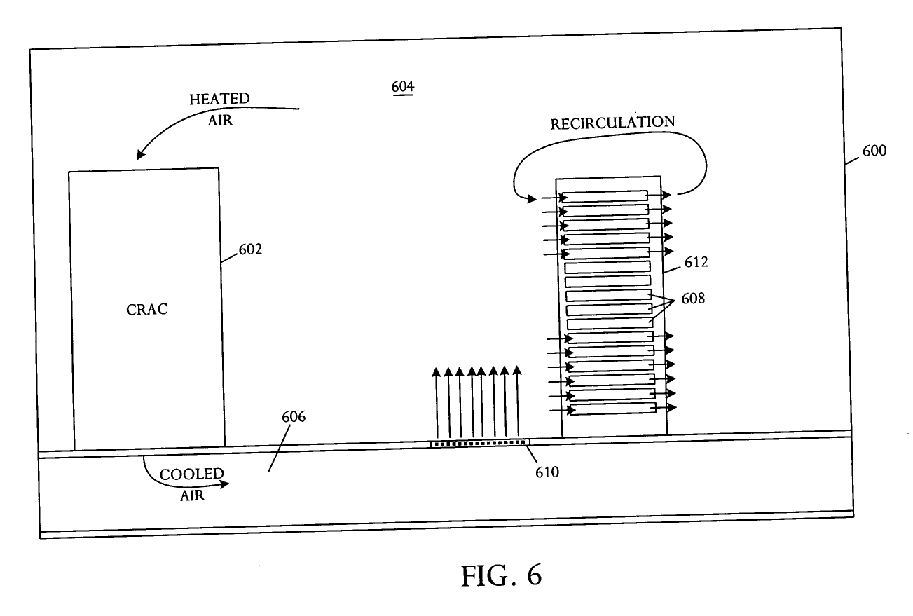

In some embodiments, a real-time dynamic airflow mapping is derived and displayed 308 showing current data center configuration and airflow throughout locations in the data center configuration. FIG. 4 is a schematic pictorial diagram illustrating an embodiment of a display of a two-dimensional air flow map. Similarly, airflow may be mapped in three dimensions as a function of the tachometer readings and fan location as depicted in FIG. 5. Airflow rate information is useful for thermal management of information technology equipment to enable airflow monitoring and either manual or automatic control of data center CRAC units to deliver sufficient cooling airflow to each rack in the data center. As shown in FIG. 5, if a rack does not receive sufficient airflow from the CRAC units via under-floor plenum perforated tiles or overhead venting, the information technology equipment will draw air from other areas of the data center, often resulting in recirculation of exhaust air and avoidable system overheating.

Referring to FIG. 3B, a flow chart depicts an embodiment of a method 310 may include automatic functionality. For example, a computer room air conditioning (CRAC) system may be controlled 312 based on the airflow mapping.

FIG. 3C is a flow chart showing an embodiment of a method 320 using various other measurements in combination with fan speed-based airflow measurements, pressure measurements and/or anemometer measurements to determine system ventilation. In various configurations, ambient temperature may be monitored 322 at various positions in the data center. Parameters and conditions such as power consumption 324 and/or software execution load 326 may be tracked in various servers distributed in the data center. System ventilation may be mapped 328 as a function of one or more of ambient temperature, in combination with the airflow mapping.

The various functions, processes, methods, and operations performed or executed by the system can be implemented as programs that are executable on various types of processors, controllers, central processing units, microprocessors, digital signal processors, state machines, programmable logic arrays, and the like. The programs can be stored on any computer-readable medium for use by or in connection with any computer-related system or method. A computer-readable medium is an electronic, magnetic, optical, or other physical device or means that can contain or store a computer program for use by or in connection with a computer-related system, method, process, or procedure. Programs can be embodied in a computer-readable medium for use by or in connection with an instruction execution system, device, component, element, or apparatus, such as a system based on a computer or processor, or other system that can fetch instructions from an instruction memory or storage of any appropriate type. A computer-readable medium can be any structure, device, component, product, or other means that can store, communicate, propagate, or transport the program for use by or in connection with the instruction execution system, apparatus, or device.

The illustrative block diagrams and flow charts depict process steps or blocks that may represent modules, segments, or portions of code that include one or more executable instructions for implementing specific logical functions or steps in the process. Although the particular examples illustrate specific process steps or acts, many alternative implementations are possible and commonly made by simple design choice. Acts and steps may be executed in different order from the specific description herein, based on considerations of function, purpose, conformance to standard, legacy structure, and the like.

Referring to FIG. 6, a schematic pictorial diagram illustrates a perspective view of a data center 600 that implements the illustrative thermal and power management techniques. During operation with the airflow tracking disabled, a computer room air conditioner (CRAC) 602 pulls heated air from the room 604 and supplies cool air to an under-floor plenum 606. Airflow to individual computers and servers 608 is controlled by the position and relative open area of perforated tiles 610. With airflow tracking disabled, as in conventional data centers, selection of the amount of airflow sufficient to cool any individual rack or cabinet 612, or any individual computer or server, is simply by estimation. For example, worst case airflow criteria for all equipment in a rack can be summed and the CRAC 602 sized to supply at least the summed airflow. The traditional technique commonly supplies an incorrect airflow amount, either too high or too low.

Difficulties may arise is the air supply to the rack is insufficient. An ideal airflow amount supplies cooled air up to the top level of the rack 612 so that every computer or server 608 in the rack receives suitable ventilation, generally entering at the front and exiting at the rear of the rack. If an inadequate airflow is supplied, cooling air and filtration extends only partially up the rack 612 so that heated air re-circulates in devices 608 in higher shelves of the rack 612, resulting in inadequate cooling. The illustrative fan speed monitoring technique enables monitoring and location-mapping of airflow in all computers and servers 608 in the rack 612, and may be implemented in a control process that adjusts the supply of cooling air to the equipment. In a particular implementation, fans in servers at lower levels of the rack may be throttled back while fans in servers at higher levels in the rack are run at higher speeds to drive airflow to higher elevations in the data center.

The airflow monitoring technique accordingly enables tailoring of airflow to match the changing conditions in the data center 600.

Multiple factors drive overall system airflow, measured in cubic feet per minute (CFM) including ambient temperature, software execution load, configuration, altitude, and other factors. Ambient temperature is a highly prominent factor so that addition of a new server into relatively hot location in a data center configuration incapable of adjusting system airflow may cause the temperature to increase uncontrollably due to re-circulation of heated air. The illustrative technique uses information such as fan speed data indicative of airflow to facilitate manual and/or automatic control of data center environment and to terminate re-circulation leading to overheating.

In the illustrative data center 600, automated thermal and power management techniques may be based on measurements of total airflow consumption including measurements of airflow derived from fan speed, pressure, and/or direct flow measurements from an anemometer and local ambient temperature information both at the front and rear of the racks 612. The information can be used to control overall system volume flow produced by computer room air conditioning 602 and to adjust the open area of perforated tiles 610 at various suitable locations in the data center 600, thereby controlling local airflow. Dynamic sensing of airflow and load information in multiple individual locations and for multiple individual heat dissipating elements enables autonomous adjustment of cooling resources based on overall and local system conditions. Automated thermal and power management further can enable energy savings, allowing cooling reduction in low-load conditions while ensuring absolute maximum cooling for high-load operations under feedback control.

Dynamic sensing of airflow enables a data center manager or user to view the amount of air drawn by each individual server 608 and accordingly can be used to facilitate arrangement and configuration of components, devices, and other structures in the data center 600. For example, airflow sensing may be used to detect overly-constrained signal cabling in a rack that impedes flow through the rack or locations in a room which are starved for air, resulting in a high ambient temperature.

Dynamic airflow sensing may also be used to make policy decisions. For example workload can be monitored for criticality of work that an individual server is performing. A server performing a higher criticality operation may be supplied with a higher airflow while another server performing a less important operation may be supplied with a lower airflow.

While the present disclosure describes various embodiments, these embodiments are to be understood as illustrative and do not limit the claim scope. Many variations, modifications, additions and improvements of the described embodiments are possible. For example, those having ordinary skill in the art will readily implement the steps necessary to provide the structures and methods disclosed herein, and will understand that the process parameters, materials, and dimensions are given by way of example only. The parameters, materials, and dimensions can be varied to achieve the desired structure as well as modifications, which are within the scope of the claims. Variations and modifications of the embodiments disclosed herein may also be made while remaining within the scope of the following claims. For example, a few specific examples of devices and techniques for monitoring airflow are described. The illustrative airflow monitoring techniques can be used with any suitable types of sensors and sensed parameters. The illustrative techniques may be used with any suitable data center configuration and with any suitable servers, computers, and devices.

What is claimed is:

1. An airflow distribution apparatus for usage in a data center comprising:
at least one airflow sensor coupled to a plurality of fans in at least one server in the data center; and
a controller coupled to the at least one sensor and configured to monitor airflow for the fan plurality and control cooling in the data center as a function of the sensed airflow.

2. The apparatus according to claim 1 further comprising:
the controller further configured to generate a real-time dynamic airflow mapping from sensed airflow.

3. The apparatus according to claim 1 further comprising:
a graphical user interface; and
the controller configured to display via the graphical user interface a real-time dynamic airflow mapping describing a current data center configuration and airflow throughout locations in the data center configuration.

4. The apparatus according to claim 1 further comprising:
a control interface coupled to a computer room air conditioning (CRAC) system; and
the controller coupled to the control interface and further configured to control the computer room air conditioning (CRAC) system as a function of sensed airflow.

5. The apparatus according to claim 1 further comprising:
the controller further configured to map airflow in three dimensions as a function of sensed airflow and fan location.

6. The apparatus according to claim 1 further comprising:
a thermometer interface adapted to couple to at least one thermometer located in at least one position in the data center; and
the controller coupled to the thermometer interface, the controller being configured to measure ambient temperature in the at least one position in the data center and to map airflow in multiple dimensions as a function of sensed airflow and fan location, the controller being further configured to map data center ventilation as a function of the airflow mappings and the at least one position ambient temperature measurement.

7. The apparatus according to claim 1 further comprising:
a server interface adapted to couple to a plurality of servers in the data center; and
the controller coupled to the server interface, the controller being further configured to monitor power consumption in the plurality of servers, map airflow in multiple dimensions as a function of sensed airflow and fan location, and control cooling in the data center as a function of server power consumption and the airflow mapping.

8. The apparatus according to claim 1 further comprising:
a server interface adapted to couple to a plurality of servers in the data center; and
the controller coupled to the server interface, the controller being further configured to monitor software execution load in the plurality of servers, map airflow in multiple dimensions as a function of sensed airflow and fan locations, and map data center ventilation as a function of server software execution load and the airflow mapping.

9. The apparatus according to claim 1 further comprising:
a thermometer interface adapted to couple to at least one thermometer located in at least one position in the data center;
a server interface adapted to couple to a plurality of servers in the data center; and
the controller coupled to the thermometer interface and the server interface, the controller being further configured to monitor software execution load in a plurality of servers in the data center and map airflow in multiple dimensions as a function of sensed airflow, fan location, the at least one position ambient temperature measurement, server power consumption, and server software execution load.

10. A ventilation system for a data center comprising:
a raised-floor overlying an under-floor plenum space;
at least one airflow sensor coupled to a plurality of fans in multiple servers arranged in at least one cabinet in the data center; and
a controller coupled to the at least one airflow sensor and configured to monitor airflow for the fan plurality and control cooling in the data center as a function of the sensed airflow.

11. The system according to claim 10 further comprising:
a graphical user interface; and
the controller configured to display via the graphical user interface a real-time dynamic airflow mapping describing a current data center configuration and airflow throughout locations in the data center configuration.

12. The system according to claim 10 further comprising:
a computer room air conditioning (CRAC) system configured to ventilate the data center; and
the controller further configured to control the computer room air conditioning (CRAC) system as a function of the airflow mapping.

13. The system according to claim 10 further comprising:
at least one thermometer located in at least one positioned the data center; and
the controller coupled to the at least one thermometer, the controller being configured to measure ambient temperature in the at least one position in the data center and to map airflow in multiple dimensions as a function of sensed airflow and fan location, the controller being further configured to map data center ventilation as a function of the airflow mappings and the at least one position ambient temperature measurement.

14. The system according to claim 10 further comprising:
a server interface adapted to couple to a plurality of servers in the data center; and
the controller coupled to the server interface and further configured to monitor power consumption in the plurality of servers, map airflow in multiple dimensions as a function of sensed and fan location, and map data center ventilation as a function of server power consumption and the airflow mapping.

15. The system according to claim 10 further comprising:
a server interface adapted to couple to a plurality of servers in the data center; and
the controller coupled to the server interface and further configured to monitor software execution load in the plurality of servers, map airflow in multiple dimensions as a function of sensed airflow and fan location, and map data center ventilation as a function of server software execution load and the airflow mapping.

16. The system according to claim 10 further comprising:
at least one thermometer located in at least one positioned the data center;
a server interface adapted to couple to a plurality of servers in the data center; and
the controller coupled to the at least one thermometer and the server interface, the controller being further configured to monitor software execution load in a plurality of servers in the data center and map airflow in multiple dimensions as a function of sensed airflow readings, fan location, the at least one position ambient temperature measurement, server power consumption, and server software execution load.

17. A method of processing airflow distribution in a data center comprising:
monitoring airflow in a ventilation system including a plurality of fans in at least one server in the data center; and
controlling cooling in the ventilation system as a function of the sensed airflow.

18. The method according to claim 17 further comprising:
mapping airflow in multiple dimensions as a function of sensed airflow and fan location.

19. The method according to claim 17 further comprising:
generating a real-time dynamic airflow measurement from the sensed airflow readings.

20. The method according to claim 17 further comprising:
displaying a real-time dynamic airflow mapping describing a current data center configuration and airflow throughout locations in the data center configuration.

21. The method according to claim 17 further comprising:
controlling a computer room air conditioning (CRAC) system from the airflow mapping.

22. The method according to claim 17 further comprising:
mapping airflow in three dimensions as a function of airflow sensor readings and fan location.

23. The method according to claim 17 further comprising:
measuring ambient temperature in at least one position in the data center;
mapping airflow in multiple dimensions as a function of airflow sensor readings and fan locations; and
mapping data center ventilation as a function of the airflow mappings and the at least one position ambient temperature measurement.

24. The method according to claim 17 further comprising:
monitoring power consumption in a plurality of servers in the data center;
mapping airflow in multiple dimensions as a function of airflow sensor readings and fan location, and
mapping data center ventilation in multiple dimensions as a function of server power consumption and the airflow mapping.

25. The method according to claim 17 further comprising:
monitoring software execution load in a plurality of servers in the data center;
mapping airflow in multiple dimensions as a function of airflow sensor readings and fan location; and
mapping data center ventilation as a function of server software execution load and the airflow mapping.

26. The method according to claim 17 further comprising:
measuring ambient temperature in at least one position in the data center;
monitoring power consumption in a plurality of servers in the data center;
monitoring software execution load in a plurality of servers in the data center; and
mapping airflow in multiple dimensions as a function of airflow sensor readings, fan location, the at least one position ambient temperature measurement, server power consumption, and server software execution load.

27. An article of manufacture comprising:
a controller usable medium having a computable readable program code embodied therein for processing airflow distribution in a data center, the computable readable program code further comprising:
a code capable of causing the controller to monitor airflow in a ventilation system including a plurality of fans in at least one server in the data center; and
a code capable of causing the controller to control cooling in the ventilation system as a function of the sensed airflow.

28. The article of manufacture according to claim 27 further comprising:
a code capable of causing the controller to display a real-time dynamic airflow mapping describing a current data center configuration and airflow throughout locations in the data center configuration; and
a code capable of causing the controller to control a computer room air conditioning (CRAC) system from the airflow mapping.

29. The article of manufacture according to claim 27 further comprising:
a code capable of causing the controller to measure ambient temperature in at least one position in the data center;
a code capable of causing the controller to monitor power consumption in a plurality of servers in the data center;
a code capable of causing the controller to monitor software execution load in a plurality of servers in the data center; and
a code capable of causing the controller to map airflow in multiple dimensions as a function of the airflow sensor readings and fan location; and
a code capable of causing the controller to map data center ventilation in multiple dimensions as a function of the airflow mapping, the at least one position ambient temperature measurement, server power consumption, and server software execution load.

30. An airflow processing apparatus for usage in a data center comprising:
means for monitoring airflow in a ventilation system including a plurality of fans in at least one server in the data center; and
means for controlling cooling in the ventilation system as a function of the sensed airflow.
